(19) United States
(12) Patent Application Publication
(10) Pub. No.: US 2022/0255209 A1
(43) Pub. Date: Aug. 11, 2022

(54) MODE CONVERTER

(71) Applicant: Fujikura Ltd., Tokyo (JP)

(72) Inventor: Yusuke Uemichi, Sakura-shi (JP)

(73) Assignee: Fujikura Ltd., Tokyo (JP)

(21) Appl. No.: 17/615,684

(22) PCT Filed: May 29, 2020
(86) PCT No.: PCT/JP2020/021304

§ 371 Date: Dec. 1, 2021

(30) Foreign Application Priority Data
Jun. 5, 2019 (JP) 2019-105418

(51) Int. Cl. H01P 5/107; H01P 3/12; H01P 3/08; H01P 3/16; H05K 1/02

(52) U.S. Cl. CPC H01P 5/107; H01P 3/121; H05K 2201/09509; H01P 3/16; H05K 1/0251; H01P 3/08

(57) ABSTRACT

Provided is a mode converter that is capable of making the reflection coefficient at the center frequency of the operation band lower than conventional ones. A mode converter (10) includes: a post-wall waveguide (PW); a microstrip line (MS); and a blind via (BV) which is configured to carry out conversion between a guide mode of the post-wall waveguide (PW) and a guide mode of the microstrip line (MS). The blind via (BV) has a tapered shape such that a cross section decreases with increasing distance from the microstrip line (MS), and the slope (θ) of a lateral surface of the blind via (BV) is not less than 5.5°.

### TECHNICAL FIELD

The present invention relates to a mode converter which carries out conversion between a guide mode of a post-wall waveguide and a guide mode of a microstrip line.

### BACKGROUND ART

Non-patent Literature 1 discloses a mode converter which includes a post-wall waveguide and a microstrip line provided on a main surface of the post-wall waveguide and which carries out mutual conversion between a guide mode of the post-wall waveguide and a guide mode of the microstrip line. In the mode converter disclosed in Non-patent Literature 1, such conversion between guide modes is achieved by use of a cylindrical blind via made in the post-wall waveguide.

### CITATION LIST

### Non-Patent Literature

[Non-patent Literature 1]
Yusuke Uemichi, et al. “A ultra low-loss silica-based transformer between microstrip line and post-wall waveguide for millimeter-wave antenna-in-package applications,” IEEE MTT-S IMS, Jun. 2014.

### SUMMARY OF INVENTION

### Technical Problem

With regard to a mode converter, the reflection coefficient at the center frequency of the operation band is preferably not greater than −20 dB. However, with regard to the mode converter disclosed in Non-patent Literature 1, the reflection coefficient at the center frequency of the operation band is greater than −20 dB in some cases, and there is still room for improvement in this regard.

An aspect of the present invention was made in view of the above issue, and an object thereof is to provide a mode converter that is capable of making the reflection coefficient at the center frequency of the operation band lower than conventional ones.

### Solution to Problem

In order to attain the above object, a mode converter in accordance with an embodiment of the present invention includes: a post-wall waveguide; a microstrip line provided on a main surface of the post-wall waveguide; and a blind via which is made in the post-wall waveguide and which is configured to carry out conversion between a guide mode of the post-wall waveguide and a guide mode of the microstrip line, and employs a configuration in which: the blind via has a tapered shape such that a cross section parallel to the main surface gradually decreases with increasing distance from the microstrip line; and a slope of a lateral surface of the blind via with respect to a line normal to the main surface is not less than 5.5°.

### Advantageous Effects of Invention

An aspect of the present invention makes it possible to provide a mode converter that is capable of making the reflection coefficient at the center frequency of the operation band lower than conventional ones.

### BRIEF DESCRIPTION OF DRAWINGS

FIG. 1 is a plan view of a configuration of a mode converter in accordance with an embodiment of the present invention.

FIG. 2 is a cross-sectional view of the configuration of the mode converter in accordance with an embodiment of the present invention.

FIG. 3 is a cross-sectional view of the shape of a blind via of the mode converter illustrated in FIGS. 1 and 2.

FIG. 4 is a graph showing the frequency dependence of a reflection coefficient of a mode converter that includes the blind via illustrated in FIG. 3.

FIG. 5 is a cross-sectional view of a variation of the blind via of the mode converter illustrated in FIGS. 1 and 2.

FIG. 6 is a graph showing the frequency dependence of a reflection coefficient of a mode converter that includes the blind via illustrated in FIG. 5.

### DESCRIPTION OF EMBODIMENTS

[Configuration of Mode Converter]

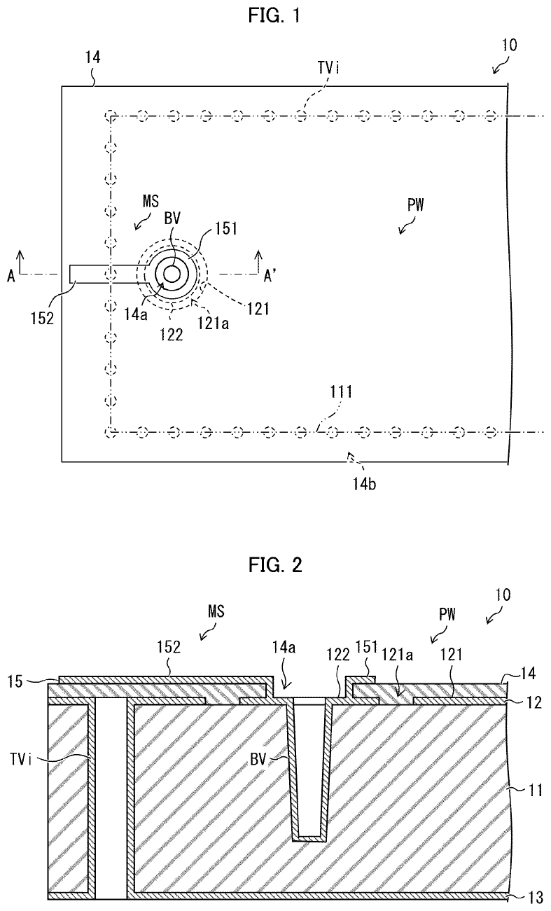

The following description will discuss a configuration of a mode converter 10 in accordance with Embodiment 1 of the present invention, with reference to FIGS. 1 and 2. FIG. 1 is a plan view of the configuration of the mode converter 10. FIG. 2 is a cross-sectional view of the configuration of the mode converter 10. Note that the cross section illustrated in FIG. 2 is a cross section of the mode converter 10 taken along line AA′ in FIG. 1.

The mode converter 10 is a device to convert a guide mode of a post-wall waveguide PW into a guide mode of a microstrip line MS, and, as illustrated in FIG. 2, includes a dielectric substrate 11, a first conductor layer 12, a second conductor layer 13, a dielectric layer 14, and a third conductor layer 15.

The dielectric substrate 11 is a plate-like member formed of a dielectric. In Embodiment 1, quartz is used as a dielectric that forms the dielectric substrate 11. Note, however, that the dielectric that forms the dielectric substrate 11 is not limited to quartz, and may be any dielectric selected appropriately according to the operation frequency of the post-wall waveguide PW and the like.

The first conductor layer 12 and the second conductor layer 13 are each a member in the form of a layer formed of a conductor. The first conductor layer 12 is provided on one main surface (top surface in FIG. 2) of the dielectric substrate 11. The second conductor layer 13 is provided on the other main surface (bottom surface in FIG. 2) of the dielectric substrate 11, and is disposed opposite the first conductor layer 12 with the dielectric substrate 11 therebetween. In Embodiment 1, copper is used as a conductor that forms the first conductor layer 12 and the second conductor layer 13. Note, however, that the conductor that forms the first conductor layer 12 and the second conductor layer 13 is not limited to copper, and may be any conductor. Furthermore, the first conductor layer 12 and the second conductor layer 13 may have any thickness. The first conductor layer 12 and the second conductor layer 13 may each be so thin that it can be called a conductor film or may each be so thick that it can be called a conductor plate.

The first conductor layer 12 is constituted by: a sheet-shaped conductor 121 having an opening 121a; and an annular conductor 122 provided within the mouth of the opening 121a. In Embodiment 1, the shape of the opening 121a as seen in plan view is a circle, and the shape of the annular conductor 122 as seen in plan view is a circular ring in which the diameter of the outer edge thereof is smaller than the diameter of the opening 12a. The outer edge of the annular conductor 122 is spaced apart from the sheet-shaped conductor 121. Therefore, the annular conductor 122 is electrically insulated from the sheet-shaped conductor 121.

In the dielectric substrate 11, a post wall 111 is provided so as to surround a specific region. In Embodiment 1, a group of a plurality of through vias TV1, TV2, and so on arranged in a fence-like manner is used as the post wall 111. Each through via TVi (i=1, 2, . . . ) is formed of a conductor layer that covers the side wall of a through hole bored in the dielectric substrate 11. One end (top end in FIG. 2) of each through via TVi is connected to the first conductor layer 12, and the other end (bottom end in FIG. 2) of the through via TVi is connected to the second conductor layer 13. Therefore, the first conductor layer 12 and the second conductor layer 13 are electrically short-circuited through the plurality of through vias TV1, TV2, and so on. The dielectric substrate 11, the first conductor layer 12, the second conductor layer 13, and the post wall 111 function as a post-wall waveguide PW whose waveguide region is a region that is sandwiched between the first conductor layer 12 and the second conductor layer 13 and that is surrounded by the post wall 111. The first conductor layer 12 and the second conductor layer 13 here function as wide walls of the post-wall waveguide PW, and the post wall 111 here functions as narrow walls (side wall and short wall) of the post-wall waveguide PW. The foregoing opening 12a in the first conductor layer 12 is located near a short wall of the post-wall waveguide PW.

The dielectric layer 14 is a member in the form of a layer formed of a dielectric. The dielectric layer 14 is provided on a main surface (top surface in FIG. 2) of the first conductor layer 12 on the opposite side of the first conductor layer 12 from the dielectric substrate 11. In Embodiment 1, a polyimide resin is used as a dielectric that forms the dielectric layer 14. Note, however, that the dielectric that forms the dielectric layer 14 is not limited to a polyimide resin, and may be any dielectric selected appropriately according to the operation frequency of the microstrip line MS and the like. Furthermore, the dielectric layer 14 may have any thickness. The dielectric layer 14 may be so thin that it can be called a dielectric film or may be so thick that it can be called a dielectric plate.

The dielectric layer 14 has an opening 14a. In Embodiment 1, the shape of the opening 14a as seen in plan view is a circle having a diameter which (1) is larger than the diameter of the inner edge of the annular conductor 122 and (2) is smaller than the diameter of the outer edge of the annular conductor 122. When seen in plan view, the opening 14a is included within the area enclosed by the outer edge of the annular conductor 122, and includes the area enclosed by the inner edge of the annular conductor 122.

The third conductor layer 15 is a member in the form of a layer formed of a conductor. The third conductor layer 15 is provided on a main surface (top surface in FIG. 2) of the dielectric layer 14 on the opposite side of the dielectric layer 14 from the first conductor layer 12-side main surface. In Embodiment 1, copper is used as a conductor that forms the third conductor layer 15. Note, however, that the conductor that forms the third conductor layer 15 is not limited to copper, and may be any conductor. Furthermore, the third conductor layer 15 may have any thickness. The third conductor layer 15 may be so thin that it can be called a conductor film or may be so thick that it can be called a conductor plate.

The third conductor layer 15 is constituted by: an annular conductor 151 which has a ring shape when seen in plan view; and a strip-shaped conductor 152 which has a strip shape when seen in plan view. In Embodiment 1, the shape of the annular conductor 151 as seen in plan view is a circular ring in which the diameter of the inner edge thereof is equal to the diameter of the opening 14a. When seen in plan view, the area enclosed by the inner edge of the annular conductor 151 coincides with the opening 14a. The inner edge of the annular conductor 151 is connected to the annular conductor 122 via a conductor layer provided on the side wall of the opening 14a. The strip-shaped conductor 152 has one end connected to the annular conductor 151, and extends in the opposite direction to the direction in which the post-wall waveguide PW extends. The width of the strip-shaped conductor 152 is smaller than the diameter of the outer edge of the annular conductor 151. The width of the strip-shaped conductor 151 is set according to the thickness of the dielectric layer 14. The dielectric layer 14, the first conductor layer 12, and the third conductor layer 15 function as a microstrip line MS whose waveguide region is a region sandwiched between the first conductor layer 12 and the third conductor layer 13. The first conductor layer 12 here functions as a ground conductor of the microstrip line MS, and the third conductor layer 15 here functions as a strip conductor of the microstrip line MS.

In the dielectric substrate 11, there is provided a blind via BV which is to carry out conversion between a guide mode of the post-wall waveguide PW and a guide mode of the microstrip line MS. The blind via BV is formed of a conductor layer that covers the side wall of a blind hole bored in one main surface (top surface in FIG. 2) of the dielectric substrate 11. When seen in plan view, the blind via BV coincides with the area enclosed by the inner edge of the annular conductor 122. One end (top end in FIG. 2) of the blind via BV is connected to the inner edge of the annular conductor 122. Therefore, the blind via BV is electrically short-circuited to the third conductor layer 15 which functions as a strip conductor of the microstrip line MS, and is electrically insulated from the first conductor layer 12 and the second conductor layer 13 which function as wide walls of the post-wall waveguide PW.

As has been described, the mode converter 10 includes: a post-wall waveguide PW; a microstrip line MS which is provided on a main surface of the post-wall waveguide PW (specifically, a top surface of the first conductor layer 12 which is part of the post-wall waveguide PW); and a blind via BV which is made in the post-wall waveguide PW (specifically, in the dielectric substrate 11 which is part of the post-wall waveguide PW) and which carries out conversion between a guide mode of the post-wall waveguide PW and a guide mode of the microstrip line MS. The mode converter 10 is characterized by the shape of the blind via BV. The following description will discuss the shape of the blind via BV with reference to other drawings.

Note that, although Embodiment 1 employs a configuration in which the blind via BV is formed of a conductor layer that covers the side wall of the blind hole, the present invention is not limited to such. For example, a configuration in which the blind via BV is formed of a conductor filling the blind hole may be employed.

[Shape of Blind Via]

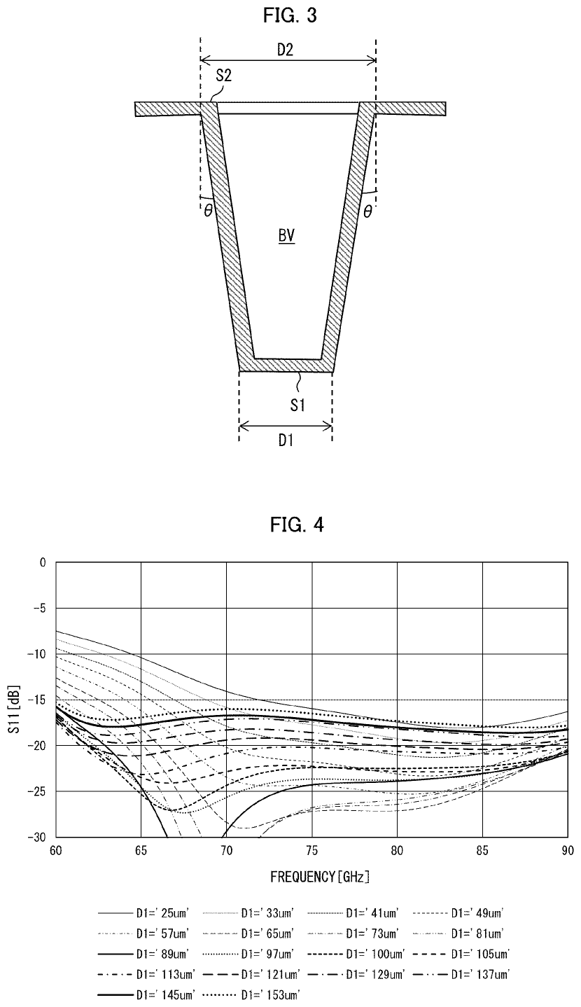

The shape of the blind via BV of the mode converter 10 is discussed with reference to FIG. 3. FIG. 3 is a cross-sectional view illustrating the shape of the blind via BV.

The blind via BV has a tapered shape such that a cross section parallel to the main surfaces of the post-wall waveguide PW decreases with increasing distance from the microstrip line MS. Specifically, in Embodiment 1, the shape of the blind via BV employed is a truncated cone shape in which a base S1 of the blind via BV on the opposite side of the blind via BV from the microstrip line MS is a planar shape as illustrated in FIG. 3. The diameter D1 of the base S1 of the blind via BV on the opposite side of the blind via BV from the microstrip line MS is smaller than the diameter D2 of a base S2 of the blind via BV on the same side of the blind via BV as the microstrip line MS. For example, the diameter D1 of the base S1 of the blind via BV on the opposite side of the blind via BV from the microstrip line MS is equal to the diameter (for example, 100 μm) of each of the through vias TVi that form the post wall 111, and the diameter D2 of the base S2 of the blind via BV on the same side of the blind via BV as the microstrip line MS is twice (for example, 200 μm) the diameter of each of the through vias TVi that form the post wall 111.

The following description will discuss, with reference to FIG. 4, a preferred diameter D1 of the base S1 of the blind via BV on the opposite side of the blind via BV form the microstrip line MS, with regard to the mode converter 10 including the blind via BV as illustrated in FIG. 3. Assume that the height H of the blind via BV is 400 μm (fixed) and that the diameter D2 of the base S2 of the blind via BV on the same side of the blind via BV as the microstrip line MS is 200 μm (fixed).

FIG. 4 is a graph showing the frequency dependence of a reflection coefficient S11 obtained when, in the mode converter 10 designed such that the center frequency of the operation band is 75 GHz, the diameter D1 of the base S1 of the blind via BV is varied from 25 μm to 153 μm in steps of 8 μm.

The graph of FIG. 4 shows that, when the diameter D1 of the base S1 of the blind via BV is not less than 49 μm and not more than 113 μm, the following preferred characteristics are achieved: the reflection coefficient S11 at the center frequency 75 GHz of the operation band is less than −20 dB. When the diameter D1 of the base S1 of the blind via BV is 49 μm, a slope θ (see FIG. 3) of the lateral surface of the blind via BV with respect to a line normal to a main surface of the dielectric substrate 11 is about 9.5°. On the other hand, when the diameter D1 of the base S1 of the blind via BV is 113 μm, the slope θ of the lateral surface of the blind via BV with respect to the line normal to the main surface of the dielectric substrate 11 is about 5.5°. Thus, the above results mean that, when the slope θ of the lateral surface of the blind via BV with respect to a line normal to a main surface of the dielectric substrate 11 is not less than 5.5° and not more than 9.5°, the following preferred characteristics are achieved: the reflection coefficient S11 at the center frequency 75 GHz of the operation band is less than −20 dB.

[Variation of Blind Via]

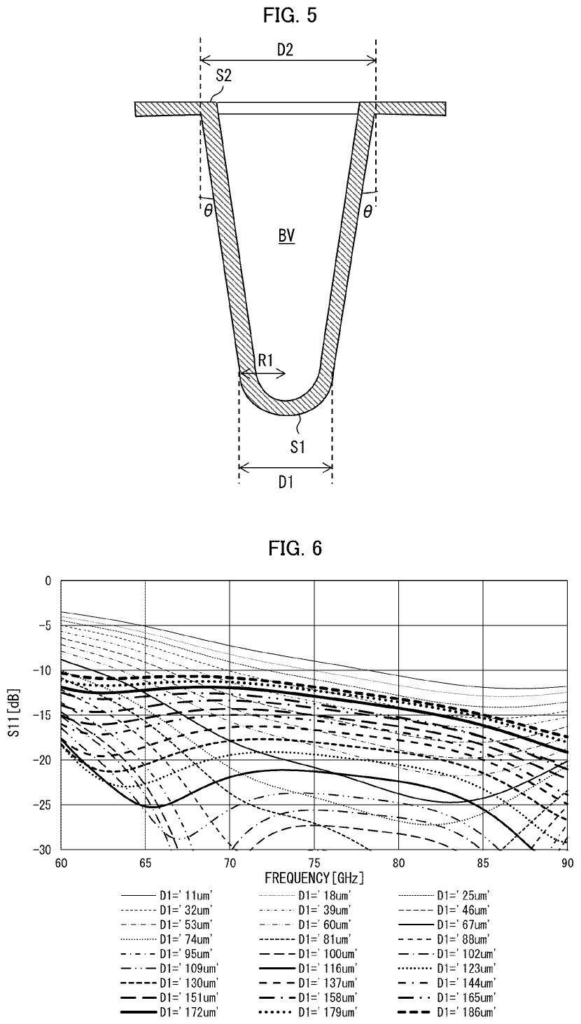

The following description will discuss a variation of the blind via BV of the mode converter 10, with reference to FIG. 5. FIG. 5 is a cross-sectional view illustrating the shape of a blind via BV in accordance with the present variation.

The blind via BV has a tapered shape such that a cross section parallel to the main surfaces of the dielectric substrate 11 decreases with increasing distance from the microstrip line MS. Specifically, in the present variation, the shape of the blind via BV employed is a substantially truncated cone shape in which the base S1 of the blind via BV on the opposite side of the blind via BV from the microstrip line MS has a spherical shape, as illustrated in FIG. 5. The diameter D1 of a base S1 of the blind via BV on the opposite side of the blind via BV from the microstrip line MS is smaller than the diameter D2 of a base S2 of the blind via BV on the same side of the blind via BV as the microstrip line MS. For example, the diameter D1 of the base S1 of the blind via BV on the opposite side of the blind via BV from the microstrip line MS is equal to the diameter (for example, 100 μm) of each of the through vias TVi that form the post wall 111, and the diameter D2 of the base S2 of the blind via BV on the same side of the blind via BV as the microstrip line MS is twice (for example, 200 μm) the diameter of each of the through vias TVi that form the post wall 111. The curvature radius R1 of the base S1 of the blind via BV on the same side of the blind via BV as the microstrip line MS is half (for example, 50 μm) the diameter D1 of the base S1 of the blind via BV on the opposite side of the blind via BV from the microstrip line MS.

The following description will discuss, with reference to FIG. 6, a preferred diameter D1 of the base S1 of the blind via BV on the opposite side of the blind via BV form the microstrip line MS, with regard to the mode converter 10 including the blind via BV as illustrated in FIG. 5. Assume that the height H of the blind via BV is 400 μm (fixed) and that the diameter D2 of the base S2 of the blind via BV on the same side of the blind via BV as the microstrip line MS is 200 μm (fixed).

FIG. 6 is a graph showing the frequency dependence of a reflection coefficient S11 obtained when, in the mode converter 10 designed such that the center frequency of the operation band is 75 GHz, the diameter D1 of the base S1 of the blind via BV is varied from 11 μm to 123 μm in steps of 7 μm.

The graph of FIG. 6 shows that, when the diameter D1 of the base S1 of the blind via BV is not less than 74 μm and not more than 116 μm, the following preferred characteristics are achieved: the reflection coefficient S11 at the center frequency 75 GHz of the operation band is less than −20 dB. When the diameter D1 of the base S1 of the blind via BV is 74 μm, a slope θ (see FIG. 5) of the lateral surface of the blind via BV with respect to a line normal to a main surface of the dielectric substrate 11 is about 8.0°. On the other hand, when the diameter D1 of the base S1 of the blind via BV is 116 μm, the slope θ of the lateral surface of the blind via BV with respect to the line normal to the main surface of the dielectric substrate 11 is about 5.5°. Thus, the above results mean that, when the slope θ of the lateral surface of the blind via BV with respect to a line normal to a main surface of the dielectric substrate 11 is not less than 5.5° and not more than 8.0°, the following preferred characteristics are achieved: the reflection coefficient S11 at the center frequency 75 GHz of the operation band is less than −20 dB.

(Preferred Slope of Lateral Surface of Blind Via)

As described above, the slope θ of the lateral surface of the blind via BV is preferably not less than 5.5°. This makes it possible to make the reflection coefficient S11 at the center frequency of the operation band equal to or less than −20 dB, regardless of whether the base S1 of the blind via BV is planar or spherical. Note that there may be cases in which the lateral surface of the blind via BV has a tapered shape for production reasons. However, the slope θ of the lateral surface, which came to having a tapered shape for production reasons, of the blind via BV would be very small and would not exceed 5.5°.

In a case where the base S1 of the blind via BV is planar, the slope θ of the lateral surface of the blind via BV is preferably not more than 9.5°. This makes it possible to make the reflection coefficient S11 at the center frequency of the operation band equal to or less than −20 dB.

In a case where the base S1 of the blind via BV is spherical, the slope θ of the lateral surface of the blind via BV is preferably not more than 8.0°. This makes it possible to make the reflection coefficient S11 at the center frequency of the operation band equal to or less than −20 dB.

Aspects of the present invention can also be expressed as follows:

A mode converter in accordance with a first aspect of the present invention includes: a post-wall waveguide; a microstrip line provided on a main surface of the post-wall waveguide; and a blind via which is made in the post-wall waveguide and which is configured to carry out conversion between a guide mode of the post-wall waveguide and a guide mode of the microstrip line, and employs a configuration in which: the blind via has a tapered shape such that a cross section parallel to the main surface gradually decreases with increasing distance from the microstrip line; and a slope of a lateral surface of the blind via with respect to a line normal to the main surface is not less than 5.5°.

The above configuration makes it possible to make the reflection coefficient at the center frequency of the operation band lower than conventional ones.

A mode converter in accordance with a second aspect of the present invention employs, in addition to the configuration of the mode converter in accordance with the first aspect, a configuration in which: a base of the blind via on an opposite side of the blind via from the microstrip line has a planar shape; and a slope of the lateral surface of the blind via with respect to the line normal to the main surface is not more than 9.5°.

The above configuration makes it possible to make the reflection coefficient at the center frequency of the operation band lower than conventional ones, when the base of the blind via on the opposite side of the blind via from the microstrip line has a planner shape.

A mode converter in accordance with a third aspect of the present invention employs, in addition to the configuration of the mode converter in accordance with the first aspect, a configuration in which: a base of the blind via on an opposite side of the blind via from the microstrip line has a spherical shape; and a slope of the lateral surface of the blind via with respect to the line normal to the main surface is not more than 8.0°.

The above configuration makes it possible to make the reflection coefficient at the center frequency of the operation band lower than conventional ones, when the base of the blind via on the opposite side of the blind via from the microstrip line has a spherical shape.

A mode converter in accordance with a forth aspect of the present invention employs, in addition to the configuration of the mode converter in accordance with the first aspect, the second aspect, or the third aspect, a configuration in which: a reflection coefficient S11 at a center frequency of an operation band is not greater than −20 dB.

The above configuration makes it possible to make the reflection coefficient at the center frequency of the operation band lower than conventional ones.

[Remarks]

The present invention is not limited to the embodiments, but can be altered by a skilled person in the art within the scope of the claims. The present invention also encompasses, in its technical scope, any embodiment derived by combining technical means disclosed in differing embodiments.

### REFERENCE SIGNS LIST

10 mode converter
PW post-wall waveguide
MS microstrip line
11 substrate
111 post wall
12 first conductor layer
13 second conductor layer
14 dielectric layer
15 third conductor layer
TVi through via
BV blind via
S1, S2 base of blind via
D1, D2 diameter of base of blind via
θ slope of blind via

1. A mode converter comprising:
a post-wall waveguide;
a microstrip line provided on a main surface of the post-wall waveguide; and
a blind via which is made in the post-wall waveguide and which is configured to carry out conversion between a guide mode of the post-wall waveguide and a guide mode of the microstrip line, wherein
the blind via has a tapered shape such that a cross section parallel to the main surface gradually decreases with increasing distance from the microstrip line, and
a slope of a lateral surface of the blind via with respect to a line normal to the main surface is not less than 5.5°.

2. The mode converter as set forth in claim 1, wherein:
a base of the blind via on an opposite side of the blind via from the microstrip line has a planar shape; and
a slope of the lateral surface of the blind via with respect to the line normal to the main surface is not more than 9.5°

3. The mode converter as set forth in claim 1, wherein:
a base of the blind via on an opposite side of the blind via from the microstrip line has a spherical shape; and
a slope of the lateral surface of the blind via with respect to the line normal to the main surface is not more than 8.0°

4. The mode converter as set forth in claim 1, wherein a reflection coefficient S11 at a center frequency of an operation band is not greater than −20 dB.
